(19) United States
(12) Patent Application Publication
(10) Pub. No.: US 2019/0221456 A1
(43) Pub. Date: Jul. 18, 2019

(54) SELECTIVE AND MULTILEVEL SOLDER PASTE PIN TRANSFER

(71) Applicant: Intel Corporation, Santa Clara, CA (US)

(72) Inventors: Dudi AMIR, Portland, OR (US); Scott MOKLER, Hillsboro, OR (US)

(21) Appl. No.: 15/870,852

(22) Filed: Jan. 12, 2018

(51) Int. Cl. H01L 21/67; H01L 23/00; B23K 3/02; H01L 21/60

(52) U.S. Cl. CPC H01L 21/67132; H01L 2021/6003; B23K 3/025; H01L 24/17

(57) ABSTRACT

Embodiments include a paste transfer tool (PTT), a semiconductor package, and a method of forming the semiconductor package with the paste transfer tool. The PTT includes a top surface and a bottom surface. The PTT also includes one or more pins, where each pin has a first end and a second end, and where the first end is disposed on the body and the second end has a nozzle tip. The method of forming the semiconductor package includes dipping the nozzle tip of the PTT in a paste reservoir to form paste dots on the nozzle tip; disposing the paste dots on one or more pads of a substrate with the PTT; and forming one or more bumps from the on paste dots on the one or more pads of the substrate, where the pads of the substrate are positioned on one or more regions of the substrate.

### FIELD

Embodiments relate to semiconductor packages. More particularly, the embodiments relate to packaging semiconductor devices using surface-mount technology (SMT).

### BACKGROUND

Packaging semiconductor devices, such as printed circuit boards (PCBs), present several problems. Some of the main problems include selective and multilevel solder paste pin transfer of solder onto a PCB. Typically, screen printing is used to transfer and apply solder paste on the PCB to attach a variety of electrical components on the PCB. This packaging solution, however, has some disadvantages.

Screen printing relies on transferring solder paste through an orifice in a screen, typically used to guide the solder paste to the appropriate pad locations on the PCB. When transferring solder paste on the PCB, the paste volume is defined by the area of the orifice, the thickness of the screen, and the transfer efficiency. Accordingly, the solder paste transfer is typically dependent on the sphere/ball size of the solder. As such, this packaging solution of screen printing can deliver any prescribed amount of solder paste onto the PCB but is only dependent (i.e., with no other variability) on the solder transferability from a reservoir to a pin then to the PCB. As the footprints, ball sizes, and pitches of the PCBs and other electrical components shrink, however the screen printing process does not scale fast enough (or cannot consistently) to meet the requirements needed to deliver the appropriate volume of solder.

These disadvantages, therefore, lead to additional problems in particular when bridging electrical components (e.g., ball grid array (BGA) packages) on the PCB as these shrinking electrical components require a small but well-defined amount of solder paste to be bridged on a defined area of the PCB. For example, standard stencil screen printing for thin/fine-pitch packages (e.g., 7 nanometers (nm) packages and smaller) is potentially unviable due to high temperature warpage that is generated as a result of a coefficient of thermal expansion (CTE) mismatch between the package and the PCB. Accordingly, the stencil screen printing is unreliable for fine-pitch packages, especially when bridging second-level interconnect (SLI) solder joints between the PCB and the attached components, such as fine-pitch BGA packages.

### BRIEF DESCRIPTION OF THE DRAWINGS

Embodiments described herein are illustrated by way of example and not limitation in the figures of the accompanying drawings, in which like references indicate similar features. Furthermore, some conventional details have been omitted so as not to obscure from the inventive concepts described herein.

FIG. 1 is a plan view of a semiconductor package with a plurality of pins and one or more high-risk areas, according to one embodiment.

FIG. 2A is a cross-sectional view of a paste transfer tool with a plurality of pins, according to one embodiment.

FIG. 2B is a cross-sectional view of a paste transfer tool with a plurality of pins dipped in a paste reservoir, according to one embodiment.

FIG. 2C is a cross-sectional view of a paste transfer tool with a plurality of pins and paste dots adheres to the pins, according to one embodiment.

FIG. 2D is a cross-sectional view of a substrate having a plurality of pads and one or more regions, according to one embodiment.

FIG. 2E is a cross-sectional view of a paste transfer tool with a plurality of pins and paste dots disposed on one or more regions of a substrate, according to one embodiment.

FIG. 2F is a cross-sectional view of a substrate after the paste is disposed on one or more regions of the substrate, according to one embodiment.

FIG. 2G is a cross-sectional view of a semiconductor package having a die, a first substrate, and a second substrate, according to one embodiment.

FIG. 3 is a cross-sectional view of a paste transfer tool with a plurality of pins and paste dots disposed on a cavity of a semiconductor package, according to some embodiments.

FIGS. 4A-4B are cross-sectional view illustrations of a system in package (SiP) using one or more paste transfer tools on one or more different regions of the SiP, according to some embodiments.

FIG. 5 is a perspective view of a paste transfer tool with a plurality of pins, according to one embodiment.

FIG. 6 is a process flow illustrating a method of forming a semiconductor package having a die, a package, and a plurality of solder balls, according to some embodiments.

FIG. 7 is a schematic block diagram illustrating a computer system that utilizes a device package (or a semiconductor package), according to one embodiment.

### DETAILED DESCRIPTION

Described herein are systems that include a selective and multilevel solder paste pin transfer tool implemented with semiconductor packages/devices and methods of forming such semiconductor packages. Specifically, a semiconductor package having a plurality of solder bumps disposed (or dispensed) with a paste transfer tool is described below and methods of forming such semiconductor package using surface-mount technology (SMT) in combination with the paste transfer tool.

In the following description, various aspects of the illustrative implementations will be described using terms commonly employed by those skilled in the art to convey the substance of their work to others skilled in the art. However, it will be apparent to those skilled in the art that the present embodiments may be practiced with only some of the described aspects. For purposes of explanation, specific numbers, materials and configurations are set forth in order to provide a thorough understanding of the illustrative implementations. However, it will be apparent to one skilled in the art that the present embodiments may be practiced without the specific details. In other instances, well-known features are omitted or simplified in order not to obscure the illustrative implementations.

Various operations will be described as multiple discrete operations, in turn, in a manner that is most helpful in understanding the present embodiments, however, the order of description should not be construed to imply that these operations are necessarily order dependent. In particular, these operations need not be performed in the order of presentation.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

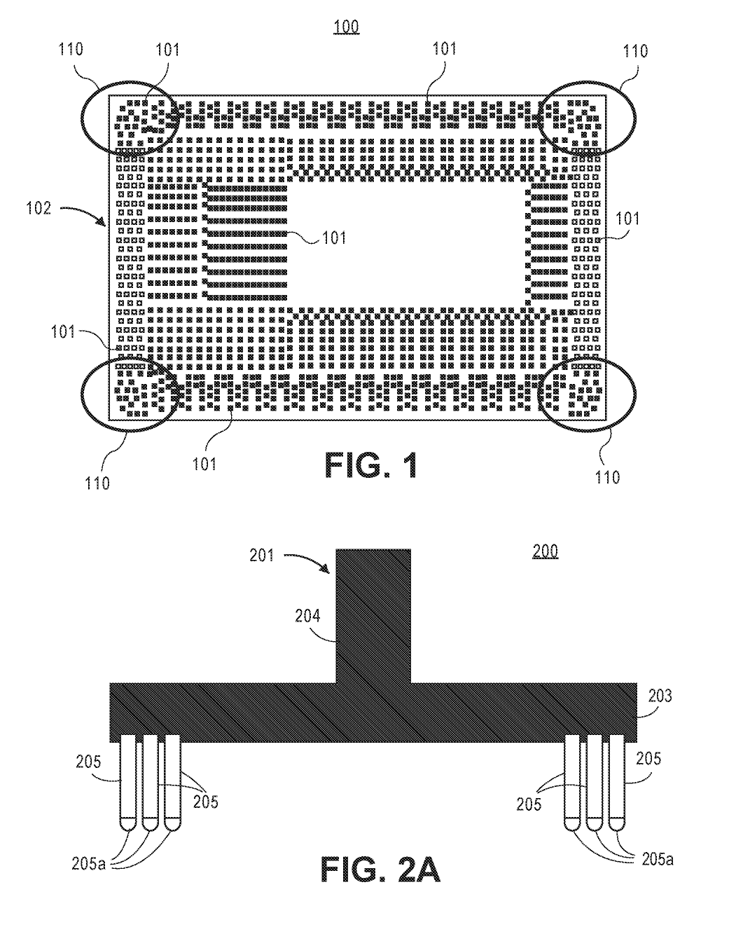

For some embodiments, a paste transfer tool is used with SMT equipment and tooling and software modifications to transfer a prescribed amount and/or a variable amount (if needed) of solder paste on to a substrate (e.g., a printed circuit board (PCB)) prior to a reflow process. As used herein, a “paste transfer tool” (also referred to as a selective transfer tool, a stamping tool, a tool, a pick and place tool, etc.) refers to a predefined paste transfer tool that may be used with a pick and place equipment to transfer paste (e.g., solder paste) to one or more regions on the substrate, where the regions include high risk areas located on the outer edges of the substrate (e.g., the regions 110 as shown in FIG. 1).

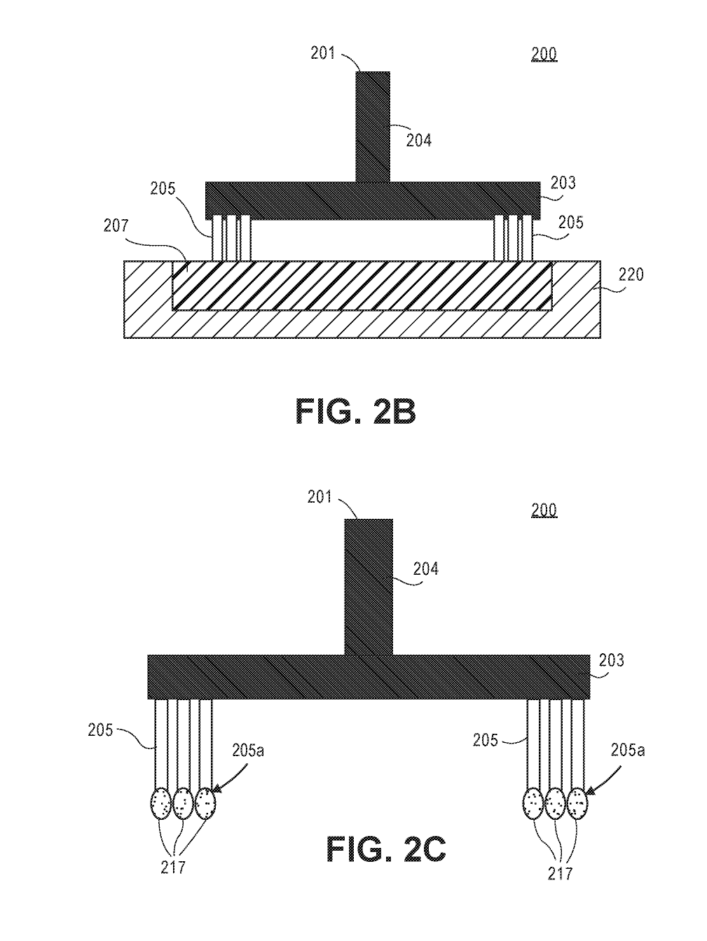

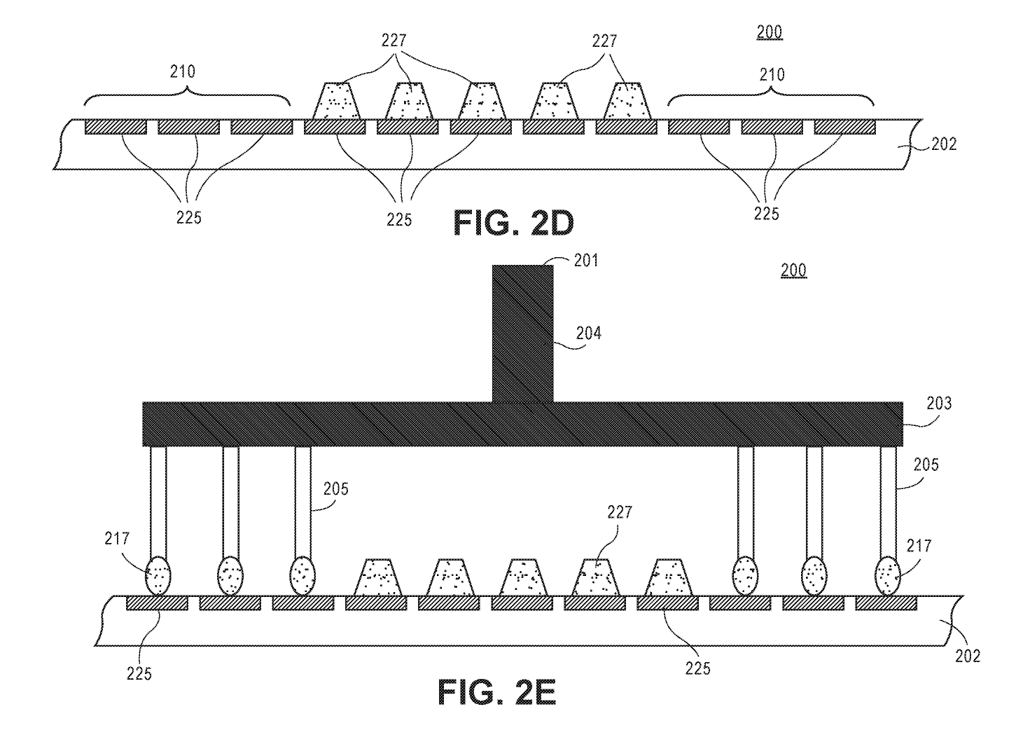

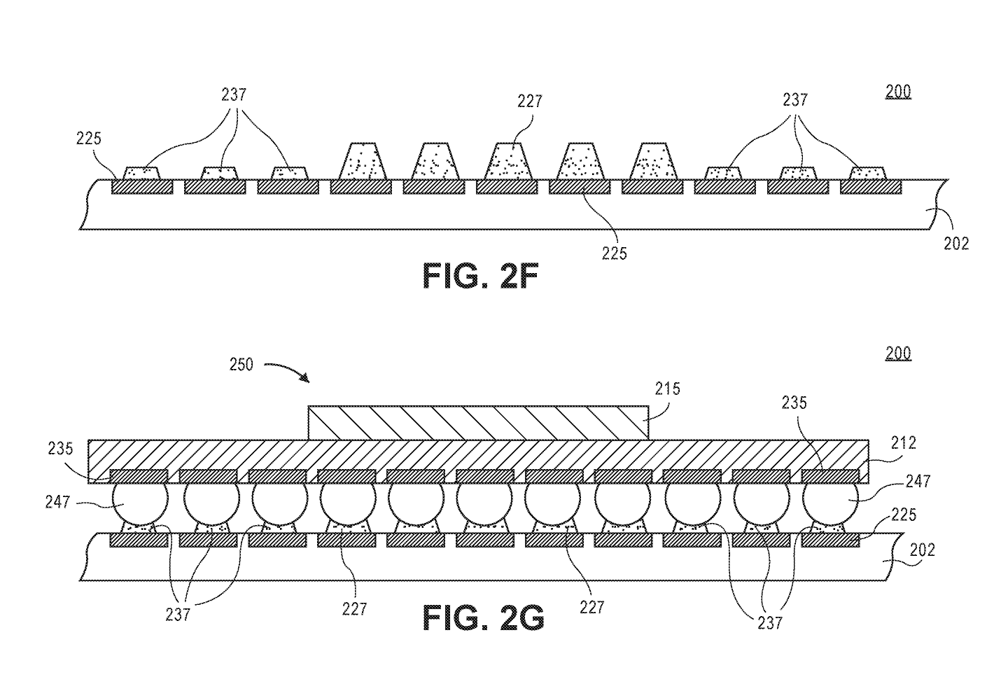

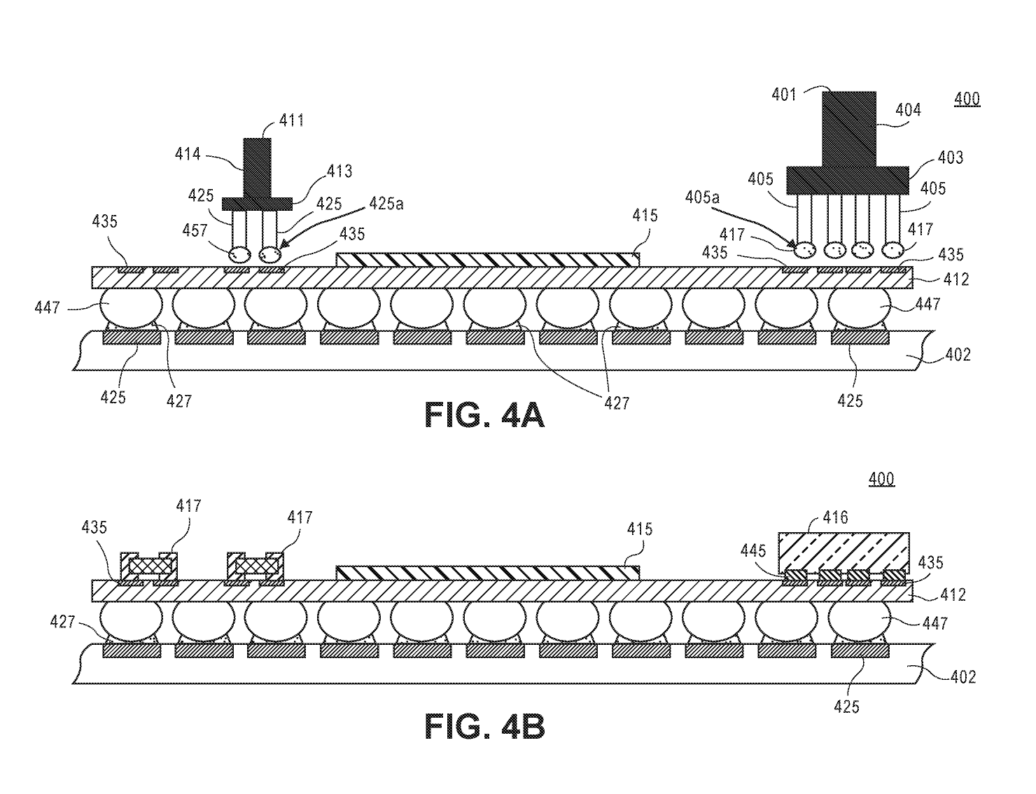

The paste transfer tool described herein includes one or more pins (or an array of pins) that match a defined/specified footprint of an area to be soldered. According to one embodiment, the pins of the paste transfer tool are dipped into a paste reservoir and then the paste is transferred and disposed on one or more pads of the substrate. For some embodiments, the volume of paste can be controlled by the dipping process (e.g., the depth, dwell, etc.) and/or the shape of the nozzle tip (also referred to as the pin tip) on the pin. In some embodiment, the paste transfer tool can be used as a stand-alone screen printing system (e.g., as shown in FIGS. 2A-2G with a semiconductor package) and/or with a standard screen printing system (e.g., as shown in FIGS. 4A-4B with a multilevel system in package (SiP)). Note that the paste transfer tool may be implemented with, but not limited to, pick and place systems, standard rework systems, and/or any other printing process systems.

These embodiments of the paste transfer tool/technology enable the selective application of solder paste volumes based on the high temperature warpage profiles of the package. This paste transfer tool helps to improve SMT packages by ensuring high quality and reliable second-level interconnect (SLI) solder joints between the substrate (e.g., the PCB) and the attached components, including ball grid array (BGA) packages. Additionally, these embodiments of the paste transfer technology allow the ability to solder a multilevel SMT semiconductor package (e.g., a three-dimensional (3D) SMT semiconductor package, a cavity-in-board SiP, a stacked SiP, etc.) in a single-pass process which helps to (i) reduce assembly cost and time and (ii) form new semiconductor packaging structures.

Additional advantages of the embodiments described herein include: (i) Enabling SMT semiconductor packaging solutions for corner bends on substrates by reducing the amount of paste on the risk areas to form bumps (or solder bumps) with a reduced z-height, area ratio (AR), and volume. For example, a substrate may have a first set of bumps disposed on a first region, and a second set of bumps (i.e., the reduced bumps) disposed on a second region (i.e., a risk area for bridging formed at the corners of the substrate during reflow) using the paste transfer tool, which may decrease the print area ratio (AR) by roughly 20% and increase the warpage margin for corner bends/bridges by roughly 20 μm. (ii) Enabling die-to-package ratios to be increased as corner bridging can be more easily allowed (or tolerated) as the warpage margin threshold is increased. (iii) Increasing warpage limit screenings for semiconductor packaging which helps to reduce scrap and cost. (iv) Enabling SMT packages to be implemented with selective and multilevel solder paste transfer in a single-pass process on at least one of a SMT package with a cavity and a SMT SiP.

FIG. 1 is a plan view of a semiconductor package 100 with a plurality of pins 101 and one or more high-risk areas 110, according to one embodiment. FIG. 1 further illustrates a BGA mapping of the semiconductor package 100 with the high-risk areas 110 for SMT bridging.

As used herein, a “high-risk area” (also referred to as a high-risk region, a risk region, a corner bend, etc.) refers to a region of a pin map on a substrate (e.g., a BGA package), where the region (e.g., at a corner of the substrate) may bend during reflow and thus form a risk area for bridging (or other coupling failures).

For one embodiment, the semiconductor package 100 includes a substrate 102 having a plurality of pins 101 and one or more high-risk regions 110 (or high-risk area pins) at the corners of the substrate 102. According to some embodiments, the substrate 102 may include, but is not limited to, a package, a BGA package, a PCB, and a motherboard. For one embodiment, the substrate 102 is a PCB. For one embodiment, the PCB is made of an FR-4 glass epoxy base with thin copper foil laminated on both sides (not shown). For certain embodiments, a multilayer PCB can be used, with pre-preg and copper foil (not shown) used to make additional layers. For example, the multilayer PCB may include one or more dielectric layers, where each dielectric layer can be a photosensitive dielectric layer (not shown). For some embodiments, holes (not shown) may be drilled in substrate 102. For one embodiment, the substrate 102 may also include conductive copper traces, metallic pads, and holes (not shown).

Accordingly, these high-risk areas 110 of the substrate 102 can be improved (or alleviated) with a paste transfer tool, where the paste transfer tool is formed/designed to have the pin location of the paste transfer tool match the print area of the substrate (as shown below in further detail in FIGS. 2A-2G).

Note that the semiconductor package 100 may include fewer or additional packaging components based on the desired packaging design.

FIGS. 2A-2G illustrate a process flow 200 of forming a semiconductor package using a paste transfer tool 201.

FIG. 2A is a cross-sectional view of a paste transfer tool 201 with a plurality of pins 205, according to one embodiment. Furthermore, FIG. 2A shows the process flow 200 forming/designing the paste transfer tool 201 used to selectively transfer paste from a paste reservoir to pads on a substrate. For one embodiment, each of the pins 205 has a nozzle tip 205a formed to transfer and dispose paste to the pad on the substrate, where the pad is located at a bridging high-risk area of the substrate.

In one embodiment, the paste transfer tool 201 includes a body 203 having a top surface and a bottom surface that is opposite from the top surface. For one embodiment, the paste transfer tool 201 also includes one or more pins 205 disposed (or positioned) on the bottom surface of the body 203. For another embodiment, the paste transfer tool 201 may have a handle 204 (or a top member) formed on the top surface of the body 203, where the handle 204 may be used to couple the paste transfer tool 201 to a pick and place system. For one embodiment, the paste transfer tool 201 may be formed with stainless steel and/or metal (or stacked metal plates with pins on the bottommost metal plate). For other embodiments, the pins 205 may be patterned into one or more sets/arrays of pins (e.g., four sets of pins) where the one or more sets of pins are positioned on the edges of the bottom surface of the body 203 to match a pre-defined print area of a substrate (e.g., each set of pins matches a set of pads on high-risk areas/corners of a substrate).

According to some embodiments, each of the pins 205 has a first end and a second end that is opposite from the first end, where the first end of the pin 205 is disposed on the bottom surface of the body 203, and the second end of the pin has the nozzle tip 205. For some embodiments, the pins 205 are spring loaded to be able to compensate for board warpage. The pin 205 may be formed with one or more different pin shapes (e.g., dome shaped, flat shaped, tapered shaped, etc.) and one or more different sizes (e.g., 150 μm, 300 um, etc.) based on the desired packaging design of the substrate. For example, the pins 205 of the paste transfer tool 201 may be used to cover one or more different print ranges (e.g., roughly from 0 to 108 cu mils). In some embodiments, the pins 205 may form bumps (e.g., as shown in FIG. 2F) having a reduced volume of paste for warpage margin.

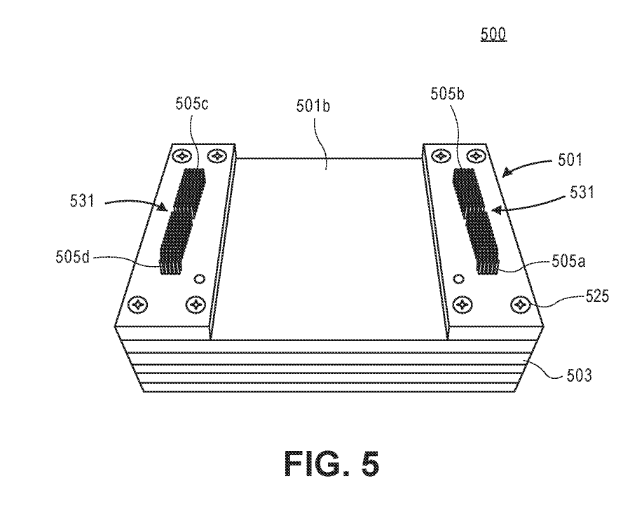

As stated above, the paste transfer tool 201 can be, but is not limited to, a stand-alone machine, a rework machine, or a SMT pick and place machine. Additionally, the paste transfer tool 201 may be formed based on one or more packaging components/applications, including, but not limited to, the size of the nozzle tips, the pick and place machine software algorithms, the paste volume information, or the process flow systems. Note that the pins 205 may be patterned on the opposite edges of the bottom surface of the body 203 (as shown in FIG. 2A), however the pins may be patterned with one or more different configurations (e.g., as shown in FIG. 4A with paste transfer tools 401 and 411, and FIG. 5 with paste transfer tool 501).

Note that the process flow 200 as shown in FIG. 2A may include fewer or additional packaging components based on the desired packaging design.

FIG. 2B is a cross-sectional view of the paste transfer tool 201 with the pins 205 dipped in a paste reservoir 220, according to one embodiment. Furthermore, FIG. 2B shows the process flow 200 coating (or dipping) the nozzle tips 205a with a paste 207 that is disposed in the paste reservoir 220. For one embodiment, the paste 207 may be a solder paste or any other type of printing paste. For another embodiment, the paste transfer tool 201 has one or more parameters used to form pre-defined paste dots (as described below in FIG. 2C). Note that the process flow 200 as shown in FIG. 2B may include fewer or additional packaging components based on the desired packaging design.

FIG. 2C is a cross-sectional view of the paste transfer tool 201 with the pins 205 and paste dots 217 adhered to the pins 205, according to one embodiment. Furthermore, FIG. 2C shows the process flow 200 forming the paste dots 217 from the paste 207 (as shown in FIG. 2B) on the nozzle tips 205a and transferring the paste dots 217 to be disposed on a substrate (as shown in FIG. 2E). For one embodiment, the paste transfer tool 201 is lifted from the paste reservoir 220 with paste dots 217 formed on each nozzle tip 217. For some embodiments, the amount of paste 217 transferred on the nozzle tip 205a is based on one or more parameters, including, but not limited to, the dwell time that the paste transfer tool 201 spends in the paste reservoir 220, the shape of the nozzle tip 205a of the pin 205 (e.g., round, flat, diamonds, etc.), and/or the diameter of the pin 205.

Note that the process flow 200 as shown in FIG. 2C may include fewer or additional packaging components based on the desired packaging design.

FIG. 2D is a cross-sectional view of a portion of a substrate 202 having a plurality of pads 225 and one or more high-risk regions 210, according to one embodiment. Furthermore, for one embodiment, FIG. 2D shows the process flow 200 disposing a first print paste on a first region to form the first set of bumps 227 on some of the pads 225 of the substrate 202. Additionally, for one embodiment, the process flow 200 excludes the pads 225 of the high-risk regions 210 from the first paste disposition. For one embodiment, the pads 225 are BGA land pads (or copper pads). Note that the first print paste used to form the first set of bumps 227 may be implemented with a paste transfer tool and/or a standard stencil screen printing.

Note that the process flow 200 as shown in FIG. 2D may include fewer or additional packaging components based on the desired packaging design.

FIG. 2E is a cross-sectional view of the paste transfer tool and the substrate 202, according to one embodiment. Furthermore, FIG. 2E shows the process flow 200 disposing the paste dots 217 on one or more second regions (i.e., the high-risk areas) of the substrate 202. For some embodiments, the paste transfer tool 201 is formed (or patterned) to have the pins 205 match the print location of the substrate 202. Note that the process flow 200 as shown in FIG. 2E may include fewer or additional packaging components based on the desired packaging design.

FIG. 2F is a cross-sectional view of the substrate 202 after the paste is disposed on the second regions of the substrate 202, according to one embodiment. Furthermore, FIG. 2F shows the process flow 200 forming a second set of bumps 237 on the pads 225 of the substrate 202 which are located on the seconds regions (or corners) of the substrate 202. As shown in FIG. 2F, the substrate 202 has reduced paste bumps 237 disposed (or deposited) on the high-risk areas, where the amount of paste transferred is controlled by the one or more parameters (as described above). For example, the paste transfer tool can enable paste transfer of roughly less than 0.55 area ratio.

For some embodiments, the process flow 200 facilitates corner bends on the substrate 202 by reducing the amount of paste on the risk areas and thus forming the second set of bumps 237, where each of these second bumps 237 has a reduced z-height, area ratio (AR), and volume. Using the paste transfer tool (e.g., the paste transfer tool 201 of 2E), the second bumps 237 mitigate bridging that is formed at the corners of the substrate 202 during reflow. Furthermore, the process flow 200 increases the warpage margin for corner bends/bridges, enables die-to-package ratios to be increased as corner bridging can be more tolerated as the warpage margin threshold is increased, and reduces the assembly screenings for warpage.

Note that the process flow 200 as shown in FIG. 2F may include fewer or additional packaging components based on the desired packaging design.

FIG. 2G is a cross-sectional view of a semiconductor package 250 having a die 215, a first substrate 212, and a second substrate 202, according to one embodiment. Note that the second substrate 202 is the same substrate 202 as shown in FIGS. 2D-2F. Furthermore, FIG. 2G shows the process flow 200 disposing the die 215 on the first substrate 212 as the first substrate 212 is disposed on the first substrate 202. For one embodiment, the die 215 includes, but is not limited to, a semiconductor die, an integrated circuit, a CPU, a microprocessor, and a platform controller hub (PCH), a memory, and a field programmable gate array (FPGA).

As shown in FIG. 2G, the first substrate 212 and the second substrate 202 are electrically coupled with a plurality of solder balls 247, where each solder ball 247 electrically couples a pad 235 on the bottom surface of the first substrate 212 and a pad 225 on the top surface of the second substrate 202. Note that a standard SMT process may be used for placement and reflow (i.e., the BGA package may be placed on the pasted lands on the PCB and then taken to a reflow oven).

For one embodiment, the semiconductor package 250 (or device) includes the die 215 disposed on the first substrate 212, where the first substrate 212 has one or more first pads 235. In one embodiment, the semiconductor package also includes the second substrate 202 having one or more second pads 225, where the one or more second pads 225 are positioned on at least a first region of the second substrate 202 and a second region (e.g., regions 210 of FIG. 2D) of the second substrate 202. The semiconductor package 250 further includes a first set of solder bumps 227 disposed on the first region of the second substrate 202, and a second set of solder bumps 237 disposed on the second region(s) (or corners) of the second substrate 202. Additionally, the semiconductor package 250 electrically couples the first substrate 212 and the second substrate 202 with a plurality of solder balls 247, where the solder balls 247 electrically couple the pads 235 of the first substrate 212 and the pads 225 of the second substrate 202.

Note that the process flow 200 as shown in FIG. 2G may include fewer or additional packaging components based on the desired packaging design.

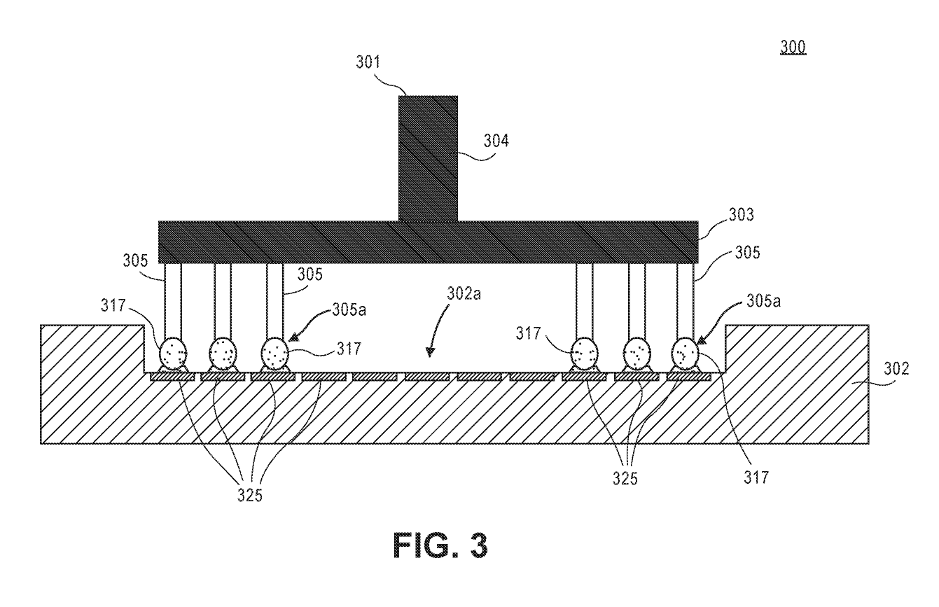

FIG. 3 is a cross-sectional view of a semiconductor package 300 having a paste transfer tool 301 with a plurality of pins 305 and paste dots 317 disposed on a cavity 302a of a substrate 302, according to some embodiments. Note that the paste transfer tool 301 and the substrate 302 may be similar to the paste transfer tool 201 and the substrate 202 of FIGS. 2A-2G, but the paste transfer tool 301 is formed to match pads 325 located on a cavity 302a of the substrate 302 (also referred to as a cavity board/package). For one embodiment, the substrate 302 may have one or more cavities 302a. For one embodiment, the cavity 302a may be formed on any region of the substrate 302.

For one embodiment, the paste transfer tool 301 enables multilevel paste transferring on the substrate 302, where the paste transfer tool 301 may be used to print paste 317 on the pads 325 on the cavity 302a, while another level of the substrate 302 may have paste printed with either the same tool or a standard printing process. As such, pin transfer using the paste transfer tool 301 enables SMT in a cavity board. Typically, screen print in a cavity is difficult and expensive, requiring either a double-pass process or the use of expensive 3D stencils. The paste transfer tool 301 can eliminate the need for stencils and increase SMT yield in packages where the risk for open joints is high. For example, cavity reflow typically requires dipping the package in paste prior to placement, unfortunately room temperature warpage results in an inconsistent paste dip process across the warped BGA field. For some embodiments, the paste transfer tool 301 adds additional paste 317 to these pads 325 on the high risk regions/locations.

Note that the semiconductor package 300 may include fewer or additional packaging components based on the desired packaging design.

FIGS. 4A-4B are cross-sectional view illustrations of a system in package (SiP) 400 using one or more paste transfer tools 401 and 411 on one or more regions of the SiP 400, according to some embodiments. Note that the SiP 400 of FIGS. 4A-4B is similar to semiconductor packages 250 and 300 of FIGS. 2-3, except that the semiconductor package 400 is multilevel and needs selective soldering on one or more region pads 435 using different paste transfer tools 401 and 411. In addition, the paste transfer tools 401 and 411 are similar to the paste transfer tools 201 and 301 of FIGS. 2-3, but these tools 401 and 411 are formed and patterned to match the pads 435 on the top level/surface of the a first substrate 412.

Referring now to FIG. 4A, the SiP 500 has stacked a die 415 on the first substrate 412 as the first substrate 412 is stacked on a second substrate 402, where the first and second substrates may be electrically coupled with solder balls 447 and bumps 427. Note that the bumps 427 on pads 425 of the second substrate 402 may be printed with a standard paste printing process. As shown in FIG. 4A, the SiP 400 uses two paste transfer tools 401 and 411.

For one embodiment, the paste transfer tool 401 includes a body 403, a top member (or handle) 404, pins 405, nozzle tips 405a (note that the tips may be obstructed by the paste dots 417), and the paste dots 417. For one embodiment, the paste transfer tool 401 is formed and patterned to match one set of pads 435 on one region of the first substrate 412. In one embodiment, the paste transfer tool 411 includes a body 413, a top member (or handle) 414, pins 425, nozzle tips 415a (note that the tips may be obstructed by the paste dots 457), and the paste dots 457. For one embodiment, the paste transfer tool 411 is formed and patterned to match another set of pads 435 on another region of the first substrate 412. Also note that the volume of paste used to form the paste dots 417 and 457 may be similar or different based on the packaging components (as shown in FIG. 4B).

Additionally, the paste transfer system shown in FIG. 4A enables SMT in a multi-level product where paste deposit is needed to be made on the second substrate 402 (e.g., a PCB) and the SiP first substrate 412. Typically, standard screen printing processes print on different SiP levels before SMT. As such, the paste transfer tools/systems (as shown in FIG. 4A) provide an improvement to SMT by enabling SiP assembly in a single reflow process during the SMT assembly line.

Referring now to FIG. 4B, after the paste transfer tools 401 and 411 dispose the paste on the pads 435 on the first substrate 412 (also referenced as the second level), one or more different components 416-417 are disposed on the on the first substrate 412 with a pick and place machine (not shown). For example, the one or more components 416-417 are electrically coupled to the pads 435 on the first substrate 412, where the pads 445 of the component 416 are electrically coupled to some of the pads 435 of the first substrate 412. For some embodiments, the component 416 may be a bottom terminated component (BTC) disposed on the first substrate 412, and the components 417 may be chip-capacitor components disposed on the first substrate 412. For example, these components 416-417 may include components such as BGA packages, quad flat packages (QFPs), BTCs, and quad flat no lead (QFN) packages, and/or any other chip/capacitor.

Note that the process flow 400 as shown in FIGS. 4A-4B may include fewer or additional packaging components based on the desired packaging design.

FIG. 5 is a perspective view of a paste transfer tool 501 with one or more sets of pins 505a-d, according to one embodiment. Note that the paste transfer tool 501 is similar to the paste transfer tools 201, 301, and 401/411 of FIGS. 2-4, but the paste transfer tool 501 may be used to transfer paste to one or more cavities on a SiP (not shown). As shown in FIG. 5, the paste transfer tool 501 has a body 503 and a bottom surface 501b that includes four sets of pins 505a-d, which are patterned to transfer paste to four edge rows for each side of a BGA package (not shown). For one embodiment, the body 503 may be one single enclosure/component or one or more stacked plates. Note that the pin sets 505a-b are separated by a gap 531 and the pin sets 505c-d are separated by another gap 531. Also note that the bottom surface 501b of the paste transfer tool 501 includes one or more screws 525 which allow the paste transfer tool 501 to interchange one or more different sets of pins to match one or more different substrate footprints.

Note that the paste transfer tool 500 may include fewer or additional packaging components based on the desired packaging design.

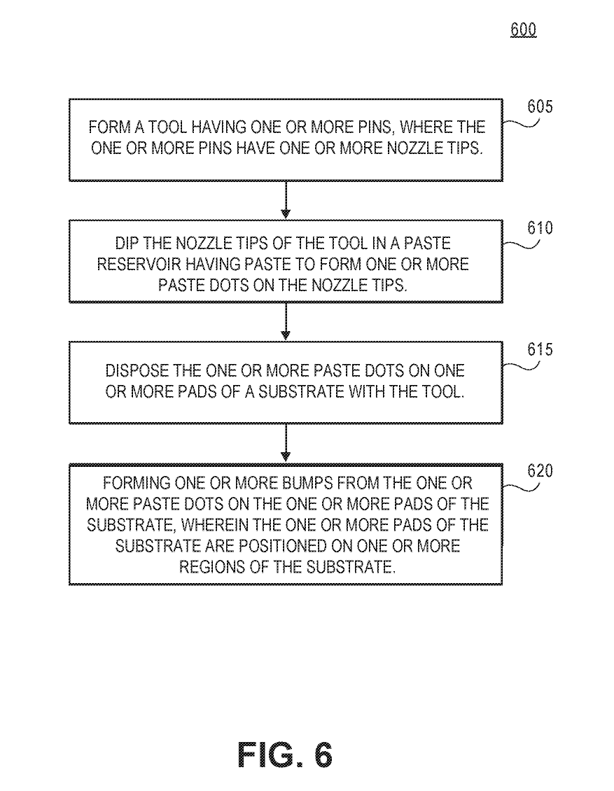

FIG. 6 is a process flow 600 illustrating a method of forming a semiconductor package having a die, a package, and a plurality of solder balls, according to some embodiments. Process flow 600 shows a method of forming a semiconductor package as shown in FIGS. 2-4. For one embodiment, process flow 600 may use a paste transfer tool (e.g., paste transfer tool 201 of FIG. 2A.

At block 605, the process flow 600 forms a tool having one or more pins, where the one or more pins have one or more nozzle tips (as shown in FIG. 2A). At block 610, the process flow 600 dips the nozzle tips of the tool in a paste reservoir having paste to form one or more paste dots on the nozzle tips (as shown in FIG. 2B). At block 615, the process flow 600 disposes the one or more paste dots on one or more pads of a substrate with the tool (as shown in FIG. 2E). At block 620, the process flow 600 forms one or more bumps from the one or more paste dots on the one or more pads of the substrate, where the one or more pads of the substrate are positioned on one or more regions of the substrate (as shown in FIG. 2F).

Note that the process flow 600 may include fewer or additional packaging steps and/or components based on the desired packaging design.

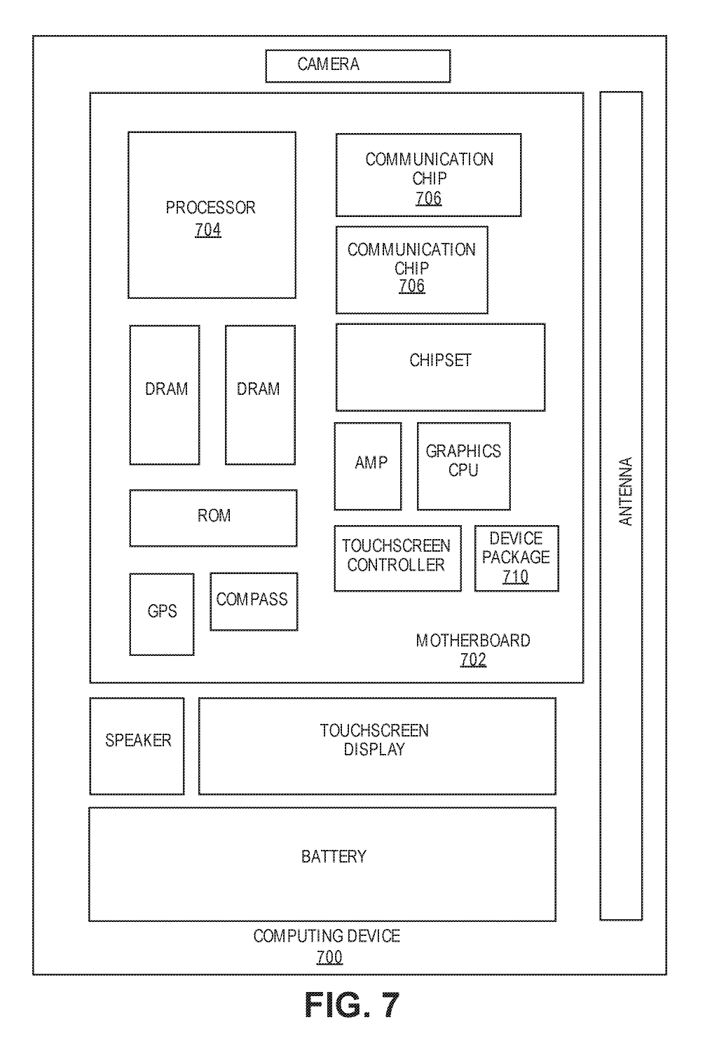

FIG. 7 is a schematic block diagram illustrating a computer system 700 that utilizes a device package 710 (e.g., a semiconductor package, a cavity package, a SiP, etc.) that has one or more electrical components and/or packages (e.g., BGA packages) stacked with solder paste using paste transfer tool(s), according to one embodiment. FIG. 7 illustrates an example of computing device 700. Computing device 700 houses motherboard 702. For one embodiment, motherboard 702 may be similar to the substrates/packages of FIGS. 2-4 (e.g., substrates 202, 302, and 402 of FIGS. 2-4). Motherboard 702 may include a number of components, including but not limited to processor 704, device package 710 (or the BCC semiconductor package/system), and at least one communication chip 706. Processor 704 is physically and electrically coupled to motherboard 702. For some embodiments, at least one communication chip 706 is also physically and electrically coupled to motherboard 702. For other embodiments, at least one communication chip 706 is part of processor 704.

Depending on its applications, computing device 700 may include other components that may or may not be physically and electrically coupled to motherboard 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 706 enables wireless communications for the transfer of data to and from computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

Processor 704 of computing device 700 includes an integrated circuit die packaged within processor 704. Device package 710 may be, but is not limited to, a packaging substrate, a PCB, a SiP, and a motherboard. The device package 710 may have one or more electrical components coupled using a paste transfer tool as described herein. Note that device package 710 may be a single component/device, a subset of components, and/or an entire system, as the materials, features, and components may be limited to device package 710 and/or any other component that needs a paste transfer tool.

For certain embodiments, the integrated circuit die may be packaged with one or more devices on a package substrate that includes a thermally stable RFIC and antenna for use with wireless communications and the device package, as described herein, to reduce the z-height of the computing device. The term “processor” may refer to any device or portion of a device that processes electronic data from registers and/or memory to transform that electronic data into other electronic data that may be stored in registers and/or memory.

At least one communication chip 706 also includes an integrated circuit die packaged within the communication chip 706. For some embodiments, the integrated circuit die of the communication chip may be packaged with one or more devices on a package substrate that includes one or more device packages, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The following examples pertain to further embodiments:

Example 1 is a tool, comprising a body having a top surface and a bottom surface that is opposite from the top surface; and one or more pins disposed on the bottom surface of the body. Each of the one or more pins has a first end and a second end that is opposite from the first end. The first end is disposed on the bottom surface of the body and the second end has a nozzle tip.

In example 2, the subject matter of example 1 can optionally include a paste reservoir having paste; and a top member on the top surface of the body. The top member is coupled to a pick and place device.

In example 3, the subject matter of any of examples 1-2 can optionally include one or more nozzle tips dipped into the paste reservoir to form one or more paste dots on the nozzle tips.

In example 4, the subject matter of any of examples 1-3 can optionally include paste dots on the nozzle tips disposed on one or more pads of a substrate to form a plurality of bumps.

In example 5, the subject matter of any of examples 1-4 can optionally include one or more pads of the substrate positioned on one or more regions of the substrate. The pins are patterned to match the one or more regions of the substrate. One or more regions are located on one or more edges of the substrate.

In example 6, the subject matter of any of examples 1-5 can optionally include one or more pads include ball grid array pads.

In example 7, the subject matter of any of examples 1-6 can optionally include nozzle tips having one or more different shapes. One or more shapes include round tips, flat tips, and diamond tips.

In example 8, the subject matter of any of examples 1-7 can optionally include the substrate as a printed circuit board.

Example 9 is a method of forming a device package, comprising: forming a tool having one or more pins. One or more pins have one or more nozzle tips; dipping the nozzle tips of the tool in a paste reservoir having paste to form one or more paste dots on the nozzle tips; disposing the one or more paste dots on one or more pads of a substrate with the tool; and forming one or more bumps from the one or more paste dots on the one or more pads of the substrate. The one or more pads of the substrate are positioned on one or more regions of the substrate.

In example 10, the subject matter of example 9 can optionally include the tool which includes a body and a top member. The top member is disposed on a top surface of the body. The top member is coupled to a pick and place device.

In example 11, the subject matter of any of examples 9-10 can optionally include one or more pins patterned to match the one or more regions of the substrate. One or more regions are located on one or more edges of the substrate.

In example 12, the subject matter of any of examples 9-11 can optionally include one or more pads include ball grid array pads.

In example 13, the subject matter of any of examples 9-12 can optionally include nozzle tips having one or more different shapes. One or more shapes include round tips, flat tips, and diamond tips.

In example 14, the subject matter of any of examples 9-13 can optionally include the substrate as a printed circuit board.

In example 15, the subject matter of any of examples 9-14 can optionally include disposing a die on a first substrate. The substrate has at least first pads and second pads.

In example 16, the subject matter of any of examples 9-15 can optionally include the first pads formed on a top surface of the first substrate. The second pads are formed on a bottom surface of the first substrate. The tool deposits one or more second paste dots on the first pads to couple to one or more electrical components on the top surface of the first substrate.

In example 17, the subject matter of any of examples 9-16 can optionally include disposing the first substrate on the substrate. The first substrate and the substrate are electrically coupled with a plurality of solder balls. The solder balls electrically couple second pads of the first substrate and the pads of the substrate.

Example 18 is a device package, comprising a die on a first substrate. The first substrate has one or more first pads; a second substrate having one or more second pads. One or more second pads are positioned on at least a first region of the second substrate and a second region of the second substrate; a first set of bumps disposed on the first region of the second substrate; and a second set of bumps disposed on the second region of the second substrate. The first substrate is disposed on the second substrate.

In example 19, the subject matter of example 18 can optionally include the first set of bumps having a first z-height and the second set of bumps has a second z-height. The first z-height is different than the second z-height.

In example 20, the subject matter of any of examples 18-19 can optionally include further comprising a tool having a body, a top member, and one or more pins. One or more pins have one or more nozzle tips. The top member is on the top surface of the body. The top member is coupled to a pick and place device. One or more pins are patterned to match the one or more pads on the second region of the second substrate; and a paste reservoir having paste.

In example 21, the subject matter of any of examples 18-20 can optionally include one or more nozzle tips are dipped into the paste reservoir to form one or more paste dots on the nozzle tips.

In example 22, the subject matter of any of examples 18-21 can optionally include paste dots on the nozzle tips disposed on the one or more pads of the second substrate to form the second set of bumps.

In example 23, the subject matter of any of examples 18-22 can optionally include the second region of the second substrate is located on one or more edges of the second substrate.

In example 24, the subject matter of any of examples 18-23 can optionally include one or more first and second pads include ball grid array pads. The substrate is a printed circuit board.

In example 25, the subject matter of any of examples 18-24 can optionally include the nozzle tips having one or more different shapes. One or more shapes include round tips, flat tips, and diamond tips.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. A tool, comprising:
a body having a top surface and a bottom surface that is opposite from the top surface; and
one or more pins disposed on the bottom surface of the body, wherein each of the one or more pins has a first end and a second end that is opposite from the first end, and wherein the first end is disposed on the bottom surface of the body and the second end has a nozzle tip.

2. The tool of claim 1, further comprising:
a paste reservoir having paste; and
a top member on the top surface of the body, wherein the top member is coupled to a pick and place device.

3. The tool of claim 1, wherein the one or more nozzle tips are dipped into the paste reservoir to form one or more paste dots on the nozzle tips.

4. The tool of claim 1, wherein the paste dots on the nozzle tips are disposed on one or more pads of a substrate to form a plurality of bumps.

5. The tool of claim 1, wherein the one or more pads of the substrate are positioned on one or more regions of the substrate, wherein the pins are patterned to match the one or more regions of the substrate, and wherein the one or more regions are located on one or more edges of the substrate.

6. The tool of claim 5, wherein the one or more pads include ball grid array pads.

7. The tool of claim 1, wherein the nozzle tips have one or more different shapes, and wherein the one or more shapes include round tips, flat tips, and diamond tips.

8. The tool of claim 4, wherein the substrate is a printed circuit board.

9. A method of forming a device package, comprising:
forming a tool having one or more pins, wherein the one or more pins have one or more nozzle tips;
dipping the nozzle tips of the tool in a paste reservoir having paste to form one or more paste dots on the nozzle tips;
disposing the one or more paste dots on one or more pads of a substrate with the tool; and
forming one or more bumps from the one or more paste dots on the one or more pads of the substrate, wherein the one or more pads of the substrate are positioned on one or more regions of the substrate.

10. The method of claim 9, wherein the tool includes a body and a top member, wherein the top member is disposed on a top surface of the body, and wherein the top member is coupled to a pick and place device.

11. The method of claim 9, wherein the one or more pins are patterned to match the one or more regions of the substrate, and wherein the one or more regions are located on one or more edges of the substrate.

12. The method of claim 9, wherein the one or more pads include ball grid array pads.

13. The method of claim 9, wherein the nozzle tips have one or more different shapes, and wherein the one or more shapes include round tips, flat tips, and diamond tips.

14. The method of claim 9, wherein the substrate is a printed circuit board.

15. The method of claim 9, further comprising disposing a die on a first substrate, wherein first substrate has at least first pads and second pads.

16. The method of claim 15, wherein the first pads are formed on a top surface of the first substrate, wherein the second pads are formed on a bottom surface of the first substrate, and wherein the tool deposits one or more second paste dots on the first pads to couple to one or more electrical components on the top surface of the first substrate.

17. The method of claim 15, further comprising disposing the first substrate on the substrate wherein the first substrate and the substrate are electrically coupled with a plurality of solder balls, and wherein the solder balls electrically couple second pads of the first substrate and the pads of the substrate.

18. A device package, comprising:
a die on a first substrate, wherein the first substrate has one or more first pads;
a second substrate having one or more second pads, wherein the one or more second pads are positioned on at least a first region of the second substrate and a second region of the second substrate;
a first set of bumps disposed on the first region of the second substrate; and
a second set of bumps disposed on the second region of the second substrate, wherein the first substrate is disposed on the second substrate.

19. The device package of claim 18, wherein the first set of bumps has a first z-height and the second set of bumps has a second z-height, and wherein the first z-height is different than the second z-height.

20. The device package of claim 18, further comprising:
a tool having a body, a top member, and one or more pins, wherein the one or more pins have one or more nozzle tips, wherein the top member is on the top surface of the body, wherein the top member is coupled to a pick and place device, and wherein the one or more pins are patterned to match the one or more pads on the second region of the second substrate; and
a paste reservoir having paste.

21. The device package of claim 20, wherein the one or more nozzle tips are dipped into the paste reservoir to form one or more paste dots on the nozzle tips.

22. The device package of claim 18, wherein the paste dots on the nozzle tips are disposed on the one or more pads of the second substrate to form the second set of bumps.

23. The device package of claim 18, wherein the second region of the second substrate is located on one or more edges of the second substrate.

24. The device package of claim 18, wherein the one or more first and second pads include ball grid array pads, and wherein the substrate is a printed circuit board.

25. The device package of claim 20, wherein the nozzle tips have one or more different shapes, and wherein the one or more shapes include round tips, flat tips, and diamond tips.
